(19) United States
(12) Patent Application Publication
(10) Pub. No.: US 2025/0037990 A1
(43) Pub. Date: Jan. 30, 2025

(54) METHOD FOR MANUFACTURING SILICON NITROGENOUS FILM ON SUBSTRATE HAVING A GROOVE

(71) Applicant: MERCK PATENT GMBH, DARMSTADT (DE)

(72) Inventor: ISSEI SAKURAI, SHIZUOKA (JP)

(21) Appl. No.: 18/919,194

(22) Filed: Oct. 17, 2024

Related U.S. Application Data
(63) Continuation of application No. PCT/EP2023/059604, filed on Apr. 13, 2023.

(30) Foreign Application Priority Data
Apr. 18, 2022 (JP) 2022-068464

(51) Int. Cl. H01L 21/02

(52) U.S. Cl. CPC H01L 21/0217; H01L 21/02222; H01L 21/02255; H01L 21/02282

(57) ABSTRACT

A method for manufacturing a silicon nitrogenous film on a substrate having a groove includes: (a) applying a silicon nitrogenous composition on a substrate having a groove to form a composition layer; (b) irradiating the composition layer with light having a wavelength of 200 to 229 nm; and (c) heating the substrate in a non-oxidizing atmosphere, wherein the refractive index of the silicon nitrogenous film is 1.70 to 2.40 for the light having a wavelength of 633 nm.

### CROSS REFERENCE TO RELATED APPLICATIONS

This application is a Continuation under 35 USC § 111 (a) of International Patent Application No. PCT/EP2023/059604, filed Apr. 13, 2023, which claims priority to Japanese Patent Application No. 2022-068464, filed Apr. 18, 2022, the entire contents of each which is incorporated herein by reference in their entirety.

### BACKGROUND OF THE INVENTION

### Technical Field

The present invention relates to a method for manufacturing a silicon nitrogenous film on a substrate having a groove.

### Background Art

A silicon nitride film is typically used as a dielectric film or a sacrificial film in the manufacture of electronic devices, especially semiconductor devices. Conventionally, the silicon nitrogenous film has been formed by CVD (Chemical Vapor Deposition) or ALD (Atomic Layer Deposition).

In the field of electronic devices, device rules are gradually becoming finer, and there is a demand for forming a silicon nitride film in a finer groove structure. As the miniaturization progresses, the occurrence of defects in film formation tends to increase, resulting in the problem of reduced efficiency in manufacturing electronic devices. In particular, the generation of joint defects (hereinafter referred to as seam) and void defects during film formation poses a problem.

Therefore, there is a desirable objective of forming a silicon nitride film using a liquid composition comprising a silicon-containing polymer. For example, a method has been proposed in which a stressed silicon nitride layer is formed by filling grooves with a liquid composition comprising a polysilazane and heating it at a high temperature in a nitrogen atmosphere as disclosed in US 2009/0289284 A1.

### SUMMARY OF THE INVENTION

### Problems to be Solved by the Invention

It is desirable for a method for manufacturing a silicon nitrogenous film on a substrate having a groove to overcome various problems including defects such as seams and voids that occur when forming a silicon nitrogenous film; low density of the silicon nitrogenous film at the bottom of the groove; low chemical resistance of the silicon nitrogenous film; a groove having a high aspect ratio that is not filled efficiently; a need for improved film quality of the silicon nitrogenous film; and low device yield.

### Means for Solving the Problems

A method for manufacturing a silicon nitrogenous film on a substrate having a groove according to the present invention includes the following steps:
(a) applying a silicon nitrogenous composition on a substrate having a groove to form a composition layer;
(b) irradiating the composition layer with light having a wavelength of 200 to 229 nm; and
(c) heating the substrate in a non-oxidizing atmosphere, wherein the refractive index of the silicon nitrogenous film is 1.70 to 2.40 for the light having a wavelength of 633 nm.

A method for manufacturing an electronic device according to the present invention comprises the above method.

### Effects of the Invention

According to the present invention, one or more of the following effects are provided. The occurrence of defects is suppressed when forming a silicon nitrogenous film; the density of the silicon nitrogenous film is high at the bottom of the groove; the chemical resistance of the silicon nitrogenous film is high; the groove having a high aspect ratio is effectively filled; the film quality of the silicon nitrogenous film is improved; and the device yield is high.

### BRIEF DESCRIPTION OF THE DRAWINGS

FIG. 1 is an electron microscope photograph after the application of hydrofluoric acid in Example 3; and

FIG. 2 is an electron microscope photograph after the application of hydrofluoric acid in Comparative Example 1.

### DETAILED DESCRIPTION OF THE INVENTION

### Mode for Carrying Out the Invention

### Definitions

Unless otherwise specified in the present specification, the definitions and examples described below are followed.

The singular form includes the plural form and “one” or “that” means “at least one”. An element of a concept can be expressed by a plurality of species, and when the amount (for example, mass % or mol %) is described, it means sum of the plurality of species.

“And/or” includes a combination of all elements and also includes single use of the element.

When a numerical range is indicated using “to” or “-”, it includes both endpoints and units thereof are common. For example, 5 to 25 mol % means 5 mol % or more and 25 mol % or less.

Alkyl means a group obtained by removing any one hydrogen from a linear, branched, or cyclic saturated hydrocarbon and includes a linear alkyl, branched alkyl or cycloalkyl and optionally includes a linear or branched alkyl in the cyclic structure as a side chain. Aryl means a group obtained by removing any one hydrogen from an aromatic hydrocarbon.

The descriptions such as “C_{x-y}”, “Cₓ-C_{y}” and “Cₓ” mean the number of carbons in a molecule or substituent. For example, C₁₋₆ alkyl means an alkyl chain having 1 or more and 6 or less carbons (methyl, ethyl, propyl, butyl, pentyl, hexyl etc.).

When polymer has plural types of repeating units, these repeating units copolymerize. These copolymerization may be any of alternating copolymerization, random copolymerization, block copolymerization, graft copolymerization, or a mixture thereof. When polymer or resin is represented by a structural formula, n, m or the like that is attached next to parentheses indicate the number of repetitions.

Celsius is used as the temperature unit. For example, 20 degrees means 20 degrees Celsius.

Wavelength means a peak wavelength at which the emission intensity of light is maximized.

The additive refers to a compound itself having a function thereof (for example, in the case of a base generator, a compound itself that generates a base). An embodiment in which the compound is dissolved or dispersed in a solvent and added to a composition is also possible. As one embodiment of the present invention, it is preferable that such a solvent is contained in the composition according to the present invention as the solvent or another component.

Hereinafter, embodiments of the present invention are described in detail.

### <Method for Manufacturing Silicon Nitrogenous Film>

The method for manufacturing a silicon nitrogenous film on a substrate having a groove according to the present invention comprises the following steps:
(a) applying a silicon nitrogenous composition on a substrate having a groove to form a composition layer;
(b) irradiating the composition layer with light having a wavelength of 200 to 229 nm; and
(c) heating the substrate in a non-oxidizing atmosphere.

### Step (a)

The step (a) is a step of applying a silicon nitrogenous composition on a substrate having a groove to form a composition layer.

In the present invention, the substrate can be a single layer or a laminate. The shape of the groove is not particularly limited. In the present invention, it is characterized in that it can easily penetrate into narrow grooves and a uniform silicon nitrogenous film can be formed inside the grooves. A substrate with grooves and holes having high aspect ratio is preferred. The shape of the groove is not particularly limited, and the cross section thereof can be any shape, such as rectangular, forward tapered, reverse tapered and curved shape. In addition, both ends of the groove can be open or closed.

The depth of the groove is preferably 150 to 500 nm, more preferably 180 to 500 nm. In one embodiment of the present invention, it is also possible to form a silicon nitrogenous film by performing the steps (a) to (c) after performing the steps (a) to (c) repeatedly for a groove deeper than 500 nm.

The ratio of the groove depth to the groove width, that is, the aspect ratio is preferably 10 to 100, more preferably 15 to 50.

Substrates having a groove include, for example, substrates for electronic devices comprising transistor devices, bit lines, capacitors, and the like. In the manufacture of such electronic devices, subsequently to the steps, forming an insulating film between a transistor device and a bit line called PMD, between a transistor device and a capacitor, between a bit line and a capacitor, or between a capacitor and a metal wiring, forming an insulating film called IMD between plural metal wirings, and filling isolation trenches, a through-hole forming step through the filled material of fine grooves can be contained.

The silicon nitrogenous composition is applied on the groove of the substrate, but there are no particular restrictions on the application method, and conventional application methods, such as spin coating method, dip coating method, spray coating method, transfer coating method and slit coating method, are included.

The preferred silicon nitrogenous compositions are described later.

A composition layer is formed by applying the silicon nitrogenous composition, if necessary, a drying step by spin drying, reduced pressure, prebaking, etc. can be performed.

In a preferred embodiment, a step of heating (prebaking) the substrate on which the composition layer is formed at 70 to 300° C., preferably 75 to 250° C. is further comprised before the step (b).

### Step (b)

The step (b) is a step of irradiating the composition layer with light having a wavelength of 200 to 229 nm.

The wavelength of the irradiation light is preferably 200 to 226 nm. In a preferred embodiment of the present invention, a KrC excimer lamp that emits ultraviolet ray with a peak wavelength of 222 nm is used for light irradiation. Although the illuminance is not particularly limited, it is preferably 2 to 80 mW/cm², more preferably 4 to 50 mW/cm². The exposure dose is preferably 4 to 100 J/cm², more preferably 7 to 80 J/cm².

The substrate can be heated during the light irradiation, the temperature is preferably 200° C. or lower, more preferably 100° C. or lower, and further preferably, the substrate is not heated.

The atmosphere during the light irradiation is not particularly limited, it is preferably a non-oxidizing atmosphere.

Condensation between the polymer occurs by the light irradiation in this step, resulting in an increase in the molecular weight of the polymer.

### Step (c)

The step (c) is a step of heating the light irradiated substrate in a non-oxidizing atmosphere.

The heating temperature in this step is preferably 400 to 1,200° C., more preferably 400 to 1,100° C. The heating time is preferably 1 minute to 10 hours, more preferably 1 to 180 minutes.

The heating atmosphere is a non-oxidizing atmosphere. The non-oxidizing atmosphere means an atmosphere having an oxygen concentration of 1% or less and a dew point of −20° C. or less. Preferably, it is N₂, Ar, He, Ne, H₂, or a mixed gas atmosphere of two or more of these, and more preferably, it is N₂ atmosphere.

After the step (c), the composition layer becomes a silicon nitrogenous film. The silicon nitrogenous film means a film comprising nitrogen atoms and silicon atoms, in which the ratio of the number of nitrogen atoms to the number of silicon atoms (N/Si) is 0.68 to 1.1, preferably 0.70 to 1.0, and it can comprise other atoms such as carbon, hydrogen and oxygen and also includes silicon carbonitride (siliconcarbonitrogenous) film.

The refractive index of the silicon nitrogenous film for light having a wavelength of 633 nm is 1.70 to 2.40, preferably 1.76 to 2.20, more preferably 1.78 to 2.20.

According to the method of the present invention, in the substrate having the silicon nitrogenous film in the groove, a uniform and dense silicon nitrogenous film is formed in the entire grooves. In particular, a uniform and dense film quality is achieved even at the bottom of the groove. As a result, the resistance to chemicals is high, and the resistance to hydrofluoric acid is particularly high.

The method for manufacturing an electronic device according to the present invention comprises the method described above. The electronic device is preferably a semiconductor device, a solar cell chip, an organic light emitting diode, an inorganic light emitting diode, more preferably a semiconductor device.

### (Silicon Nitrogenous Composition)

The silicon nitrogenous composition (hereinafter sometimes referred to as the composition) used in the present invention is not particularly limited as long as it contains a component capable of forming a silicon nitrogenous film.

The viscosity of the silicon nitrogenous composition is preferably 0.55 to 1.80 mPa·s, more preferably 0.55 to 1.70 mPa·s, more preferably 0.57 to 1.60 mPa·s as measured by a capillary viscometer at 25° C.

### (Silicon-Containing Polymer)

The composition according to the invention preferably comprises a silicon-containing polymer selected from polysilazane, polycarbosilazane and mixtures thereof.

The mass average molecular weight of the silicon-containing polymer is preferably 1,000 to 30,000, more preferably 2,000 to 30,000, further preferably 3,000 to 30,000. In the present invention, the mass average molecular weight means a mass average molecular weight in terms of polystyrene, which can be measured by the gel permeation chromatography based on polystyrene. The same is applied to other polymers.

The content of the silicon-containing polymer is preferably larger in order to prevent vaporization of low-molecular-weight components and suppress changes in volume when filled in fine groove. On the other hand, a low viscosity is preferred for good coatability, and good filling even in trenches having high aspect ratio. For these reasons, the content of the silicon-containing polymer is preferably 0.1 to 40 mass %, more preferably 0.2 to 30 mass %, based on the total mass of the composition. Although not to be bound by theory, when the content of the silicon-containing polymer is within the above range, the coating film formed in the grooves can be suppressed becoming a lower density at the bottom of the groove due to shrinkage during heating, and it is effective for making higher the density of the silicon nitrogenous film at the bottom of the groove.

### (Polysilazane)

The structure of the polysilazane used in the present invention is not particularly limited, and any polysilazane can be freely selected depending on the purpose. The polysilazane has a Si—N bond as a main skeleton, can be either an inorganic compound or an organic compound, and can have a linear, branched, or partially cyclic structure.

Preferably, the polysilazane contains 20 or more, preferably 20 to 350, repeating units selected from the group consisting of the following formulae (1-i) to (1-vi). It is preferable that each repeating unit is directly bonded without intervening repeating units other than (1-i) to (1-vi).

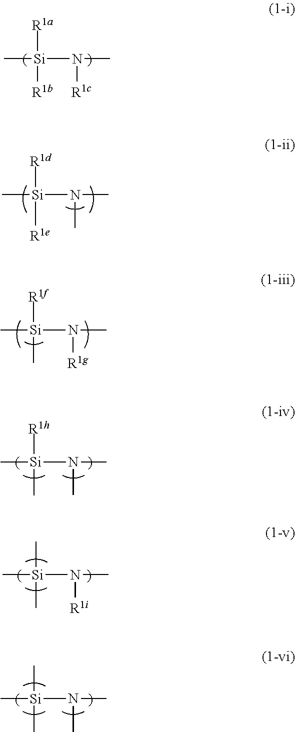

wherein,
R^{1a} to R¹ⁱ are each independently hydrogen or C₁₋₄ alkyl.

More preferably, the polysilazane used in the present invention is perhydropolysilazane (hereinafter referred to as PHPS). PHPS is a silicon-containing polymer comprising Si—N bonds as repeating units and consisting only of Si, N and H. In this PHPS, except Si—N bond, all elements binding to Si or N are H and any other elements such as carbon or oxygen are not substantially contained. The simplest structure of the perhydropolysilazane is a chain structure having a repeating unit of the following formula.

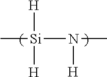

The structure of PHPS is not limited as long as it contains Si—N bonds as the repeating unit and is a silicon-containing polymer consisting only of Si, N and H, and can take various structures other than those exemplified above. PHPS preferably is one having a cyclic structure or a crosslinked structure, particularly a crosslinked structure.

The mass average molecular weight of the polysilazane is preferably 1,000 to 30,000, more preferably 2,000 to 25,000, further preferably 3,000 to 20,000, from the viewpoint of solubility in solvents and reactivity.

### (Polycarbosilazane)

The structure of the polycarbosilazane used in the present invention is not particularly limited, and any polycarbosilazane can be freely selected depending on the purpose. The polycarbosilazane has a C—Si—N structure as a main skeleton, and preferably comprises a repeating unit represented by the following formula (2-i) and a repeating unit represented by the following formula (2-ii).

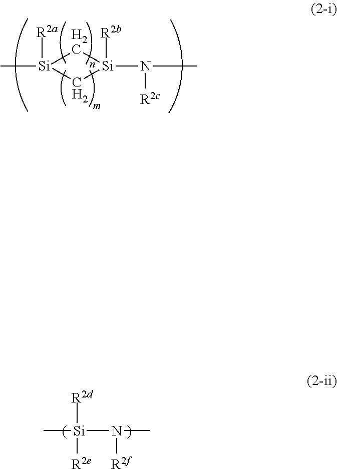

wherein,
R^{2a}, R^{2b} and R^{2c} are each independently a single bond, hydrogen, or C₁₋₄ alkyl, preferably a single bond or hydrogen.
R^{2d}, R^{2e} and R^{2f} are each independently a single bond or hydrogen. Provided that, when R^{2a}, R^{2b}, R^{2d} and R^{2e} are single bonds, they are bonded to N contained in other repeating units, and when R^{2c} and R^{2f} are single bonds, they are bonded to Si contained in other repeating units.

n and m are each independently 1 to 3, preferably 1 or 2, more preferably 1.

The polycarbosilazane is preferably polyperhydro-carbosilazane. The polyperhydrocarbosilazane has R^{2a}, R^{2b} and R^{2c} each being a single bond or hydrogen, and has no hydrocarbon groups other than (CH₂)ₙ and (CH₂) m in the formula (2-i).

The terminal group of the polycarbosilazane is preferably-SiH₃.

The polycarbosilazane according to the present invention preferably consists substantially of the repeating unit represented by the formula (2-i) and the repeating unit represented by the formula (2-ii). In the present invention, “substantially” means that 95 mass % or more of all structural units contained in the polycarbosilazane are the repeating unit represented by the formula (2-i) and the repeating unit represented by the formula (2-ii). More preferably, the polycarbo-silazane contains no repeating units other than the repeating unit represented by the formula (2-i) and the repeating unit represented by the formula (2-ii).

The mass average molecular weight of the polycarbosilazane according to the present invention is preferably 1,000 to 25,000, more preferably 2,000 to 20,000.

### (Solvent)

The composition used in the present invention can comprise a solvent. This solvent is selected from those that uniformly dissolve or disperse each component contained in the composition. Specifically, the solvent includes, for example, ethylene glycol monoalkyl ethers, such as ethylene glycol monomethyl ether, ethylene glycol monoethyl ether, ethylene glycol monopropyl ether and ethylene glycol monobutyl ether; diethylene glycol dialkyl ethers, such as diethylene glycol dimethyl ether, diethylene glycol diethyl ether, diethylene glycol dipropyl ether and diethylene glycol dibutyl ether; ethylene glycol alkyl ether acetates, such as methyl cellosolve acetate and ethyl cellosolve acetate; propylene glycol monoalkyl ethers, such as propylene glycol monomethyl ether (PGME) and propylene glycol monoethyl ether; propylene glycol alkyl ether acetates, such as propylene glycol monomethyl ether acetate (PGMEA), propylene glycol monoethyl ether acetate and propylene glycol monopropyl ether acetate; aromatic hydrocarbons, such as benzene, toluene, xylene and mesitylene; ethers, such as propylene glycol dimethyl ether, dipropyl ether, dibutyl ether and anisole; ketones, such as methyl ethyl ketone, acetone, methyl amyl ketone, methyl isobutyl ketone and cyclohexanone; alcohols, such as isopropanol and propanediol; and alicyclic hydrocarbons, such as cyclooctane and decalin. Xylene, dibutyl ether and propylene glycol dimethyl ether are preferred.

These solvents can be used alone or in combination of two or more. The content of the solvent is preferably 60 to 99.9 mass %, more preferably 70.0 to 99.8% mass %, based on the total mass of the composition.

The composition used in the present invention can be combined with further optional components as necessary. The optional component includes, for example, surfactants. The content of the optional components excluding the solvent in the entire composition is preferably 10 mass % or less, more preferably 5 mass % or less, further preferably 1 mass % or less, based on the total mass. In one embodiment of the present invention, the composition used in the present invention contains no ingredients other than the silicon-containing polymer and the solvent.

### EXAMPLE

Hereinafter, the present invention is described with reference to Examples. These Examples are for explanation and do not intend to limit the scope of the present invention.

### Synthesis Example 1: Synthesis of Polysilazane 1

After replacing the inside of a 10 L reaction vessel equipped with a cooling condenser, a mechanical stirrer and a temperature controller with dry nitrogen, 7,500 ml of dry pyridine is added into the reaction vessel and it is cooled to 0° C. 500 g of dichlorosilane is added to form a white solid adduct (SiH₂Cl₂. 2C₅H₅N). After confirming that the reaction mixture is cooled to 0° C. or lower, 350 g of ammonia is slowly introduced into it while stirring. Subsequently, after continuing to stir for 30 minutes, dry nitrogen is introduced into the liquid layer for 30 minutes to remove excess ammonia. The resulting slurry product is subjected to pressure filtration using a Teflon (registered trademark) 0.2 μm filter under a dry nitrogen atmosphere to obtain 6,000 ml of a filtrate. Pyridine is distilled off using an evaporator, and dibutyl ether is added to obtain a 20.4 mass % Polysilazane 1 dibutyl ether solution. Filtration is performed using a Teflon 0.05 μm filter to prepare a silicon nitride composition. The mass average molecular weight (hereinafter referred to as Mw) of the resulting Polysilazane 1 as measured by gel permeation chromatography (GPC) is 1,580 in terms of polystyrene.

GPC is measured using Alliance (Trademark) e2695 type high-speed GPC system (manufactured by Nippon Waters K.K.) and Super Multipore HZ—N type GPC column (manufactured by Tosoh Corporation). The measurement is conducted using monodispersed polystyrene as a standard sample and chloroform as an eluent, under the measuring conditions of a flow rate of 0.6 ml/min and a column temperature of 40° C., the mass average molecular weight is calculated as a relative molecular weight to the standard sample.

The same measuring method is applied to the following Mw.

### (Synthesis of Intermediate (A))

After replacing the inside of a 10 L reaction vessel equipped with a cooling condenser, a mechanical stirrer and a temperature control device with dry nitrogen, 7,500 ml of dry pyridine is added into the reaction vessel and it is cooled to −3° C. 500 g of dichlorosilane is added to form a white solid adduct (SiH₂Cl₂·2C₅H₅N). After confirming that the reaction mixture becomes −3° C. or lower, 350 g of ammonia is slowly introduced into it while stirring. Subsequently, after continuing to stir for 30 minutes, dry nitrogen is introduced into the liquid layer for 30 minutes to remove excess ammonia. The resulting slurry product is subjected to pressure filtration using a Teflon 0.2 μm filter under a dry nitrogen atmosphere to obtain 6,000 ml of a filtrate. Pyridine is distilled off using an evaporator, and xylene is added to obtain a 39.8 mass % polysilazane xylene solution. The Mw of the resulting polysilazane is 1,220. The polysilazane obtained by this preparation is hereinafter referred to as Intermediate (A).

### Synthesis Example 2: Synthesis of Polysilazane 2

After replacing the inside of a 10 L reaction vessel equipped with a cooling condenser, a mechanical stirrer and a temperature controller with dry nitrogen, 4,700 g of dry pyridine, 150 g of dry xylene and 1,650 g of the 39.8 mass % Intermediate (A) obtained above are added. Then, while bubbling nitrogen gas at 0.5 NL/min, the mixture is stirred so as to be uniform. Subsequently, a reforming reaction is carried out at 100° C. for 10.5 hours to obtain Polysilazane 2. The Mw of Polysilazane 2 is 3,200. After xylene is distilled off, dibutyl ether is added to obtain a 19.8 mass % Polysilazane 2 dibutyl ether solution. Filtration is performed using a Teflon 0.05 μm filter to prepare a silicon nitrogenous composition. The relative value of the total amount of SiH₂ and SiH₁ (R(SiH_{1,2})) based on the aromatic ring hydrogen in xylene is 0.245, and the relative value of NH(R(NH)) based on the aromatic ring hydrogen in xylene is 0.058.

### Synthesis Example 3: Synthesis of Polysilazane 3

In Synthesis Example 2, changing the conditions for the reforming reaction to 110° C. for 10.5 hours, the synthesis is performed to obtain a 19.2 mass % Polysilazane 3 dibutyl ether solution. Filtration is performed using a Teflon 0.05 μm filter to prepare a silicon nitrogenous composition. Polysilazane 3 has a Mw of 8,600, a R(SiH_{1,2}) of 0.198, and a R(NH) of 0.043.

### Synthesis Example 4: Synthesis of Polycarbosilazane

After replacing the inside of a 1 L reaction vessel equipped with a cooling condenser, a mechanical stirrer and a temperature controller with dry nitrogen, 500 ml of dry pyridine is added into the reaction vessel and it is cooled to −3° C. 12.3 g of dichlorosilane and 2.75 g of 1,1,3,3-tetrachloro-1,3-disilacyclobutane are added. After confirming that the reaction mixture is becomes 0° C. or lower, 11.3 g of ammonia is slowly introduced into it while stirring. Subsequently, after continuing to stir for 30 minutes, dry nitrogen is introduced into the liquid layer for 30 minutes to remove excess ammonia. The resulting slurry product is subjected to pressure filtration using a Teflon 0.2 μm filter under a dry nitrogen atmosphere to obtain 400 ml of a filtrate. After pyridine is distilled off from the filtrate, xylene is added to obtain a 19.2 mass % polycarbosilazane xylene solution. Filtration is performed using a Teflon 0.05 μm filter to prepare a silicon nitrogenous composition. The Mw of polycarbosilazane is 5,400.

### Example 1

The silicon nitrogenous composition comprising Polysilazane 1 obtained in Synthesis Example 1 is dropped on a silicon wafer (8 inches) having a pattern (grooves of width: 20 nm, length: 2 mm and depth: 500 nm) formed thereon and spin-coated at a rotational speed of 1,000 rpm to form a coating film. Prebaking is performed on a hot plate under the conditions of 80° C./N₂/3 minutes to dry the coating film. Excimer 222 nm irradiation unit MEUTA-1-200-222-M (M.D.COM inc) is used to irradiate light of 222 nm with an illuminance of 50 mW/cm² for 30 minutes. The irradiated film is annealed under the conditions of 450° C./N₂/60 minutes to obtain a silicon nitrogenous film. It is confirmed that the obtained film is a silicon nitrogenous film because a peak is observed at 820 cm⁻¹ in the Fourier transform infrared spectrum, the N/Si ratio is 0.78 by Rutherford back scattering analysis, and the refractive index is 1.78.

Neither seams nor voids are observed in the evaluation of resistance to hydrofluoric acid at the bottom of the grooves.

### Examples 2 to 6 and Comparative Examples 1 and 2

Silicon nitrogenous films are obtained in the same manner as in Example 1, except that the silicon nitrogenous composition used, the wavelength of the irradiation light, and the annealing conditions are changed as shown in Tables 1-1 and 1-2. The evaluation results are summarized in Tables 1-1 and 1-2

TABLE 1-1

| | Example 1 | Example 2 | Example 3 | Example 4 |
|---|---|---|---|---|
| | Silicon | Silicon | Silicon | Silicon |
| | nitrogenous | nitrogenous | nitrogenous | nitrogenous |
| | composition | composition | composition | composition |
| Silicon | comprising | comprising | comprising | comprising |
| nitrogenous | Polysilazane | Polysilazane | Polysilazane | Polysilazane |
| composition | 1 | 2 | 3 | 3 |
| Irradiation light | 222 | 222 | 222 | 207 |
| (nm) | | | | |
| Annealing | 450° C./N₂/ | 450° C./N₂/ | 450° C./N₂/ | 600° C./N₂/ |
| (temperature/ | 60 minutes | 60 minutes | 60 minutes | 60 minutes |
| atmosphere/ | | | | |
| time) | | | | |
| Refractive | 1.78 | 1.86 | 1.89 | 2.14 |
| index | | | | |
| Resistance to | A | A | A | A |
| hydrofluoric | | | | |
| acid | | | | |

TABLE 1-2

| | | | Comparative | Comparative |
|---|---|---|---|---|
| | | Example 6 | Example 1 | Example 2 |
| | Example 5 | Silicon | Silicon | Silicon |
| | Silicon | nitrogenous | nitrogenous | nitrogenous |
| | nitrogenous | composition | composition | composition |
| Silicon | composition | comprising | comprising | comprising |
| nitrogenous | comprising | Polysilazane | Polysilazane | Polysilazane |
| composition | Polycarbosilazane | 3 | 3 | 3 |
| Irradiation | 222 | 222 | 190 | 230 |
| light | | | | |
| (nm) | | | | |
| Annealing | 450° C./N₂/ | 1000° C./N₂/ | 450° C./N₂/ | 450° C./N₂/ |
| (temperature/ | 60 minutes | 60 minutes | 60 minutes | 60 minutes |
| atmosphere/ | | | | |
| time) | | | | |
| Refractive | 1.96 | 2.18 | 1.75 | 1.65 |
| index | | | | |
| Resistance to | A | A | C | B |
| hydrofluoric | | | | |
| acid | | | | |

### (Refractive Index)

The measurement of a value at a wavelength of 633 nm is performed in the atmosphere at room temperature using a spectroscopic ellipsometer M-2000V (manufactured by J.A. Woollam).

### (Fourier Transform Infrared Spectroscopic Analysis)

Using a Fourier transform infrared spectrophotometer FTIR-6600FV (manufactured by JASCO Corporation), the measurement is performed at room temperature by the transmission method.

### (Rutherford Back Scattering Analysis)

Using Pelletron 3SDH (manufactured by National Electrostatics Corporation), the elemental analysis is performed by Rutherford back scattering spectroscopy to measure the N/Si ratio.

### (Resistance to Hydrofluoric Acid at the Bottom of the Grooves)

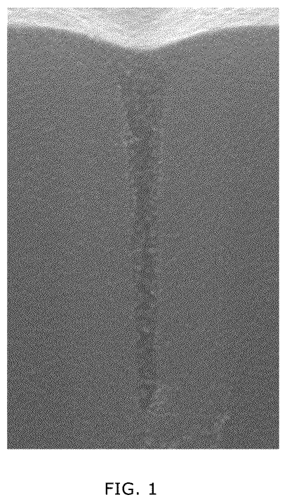

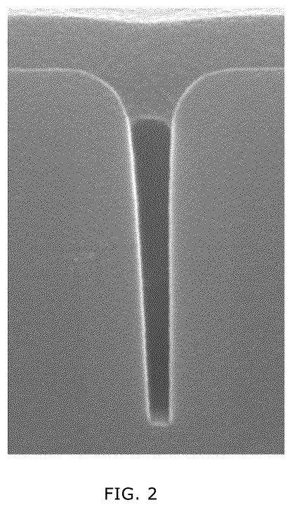

The patterned substrate after annealing is cut perpendicularly to the direction of the grooves, and the cut ones are immersed in an aqueous solution containing a 0.05 mass % of hydrofluoric acid for 30 seconds, washed with pure water, dried and then observed with a scanning electron microscope Regulus 8230 (manufactured by Hitachi High-Tech Fielding), and evaluated according to the following criteria. Electron microscope photographs of the grooves observed in Example 3 and Comparative Example 1 are shown in FIGS. 1 and 2, respectively. FIG. 1 shows no seams or voids and that a dense film is formed in the grooves. FIG. 2 shows that the obtained film in the groove has no resistance to hydrofluoric acid and that a hollow is observed.
A: Neither seams nor voids are observed at the bottom of the groove.
B: Seams or voids are observed at the bottom of the groove.
C: Significant seams or voids are observed at the bottom of the groove.

1. A method for manufacturing a silicon nitrogenous film on a substrate having a groove comprising:
(a) applying a silicon nitrogenous composition on a substrate having a groove to form a composition layer;
(b) irradiating the composition layer with light having a wavelength of 200 to 229 nm; and
(c) heating the substrate in a non-oxidizing atmosphere, wherein the refractive index of the silicon nitrogenous film is 1.70 to 2.40 for the light having a wavelength of 633 nm.

2. The method according to claim 1, wherein the depth of the groove is 150 to 500 nm.

3. The method according to claim 1, wherein the silicon nitrogenous composition comprises a silicon-containing polymer selected from polysilazane, polycarbosilazane and a mixture thereof.

4. The method according to claim 3, wherein the mass average molecular weight of the silicon-containing polymer is 1,000 to 30,000.

5. The method according to claim 1, wherein the silicon nitrogenous composition further comprises a solvent.

6. The method according to claim 5, wherein the content of the silicon-containing polymer is 0.1 to 40 mass % based on the total amount of the silicon nitrogenous composition.

7. The method according to claim 1, wherein the viscosity as measured by a capillary viscometer at 25° C. of the silicon nitrogenous composition is 0.55 to 1.80 mPa·s.

8. The method according to claim 1, further comprising a step of heating the substrate on which the composition layer is formed at 70 to 300° C. before the step (b).

9. The method according to claim 1, wherein the heating in the step (c) is performed at 400 to 1,200° C.

10. A substrate having the silicon nitrogenous film in the groove, which is obtained by the method according to claim 1.

11. A method for manufacturing an electronic device, comprising the method according to claim 1.
